(19) United States
(12) Patent Application Publication
(10) Pub. No.: US 2017/0213897 A1
(43) Pub. Date: Jul. 27, 2017

(54) METHOD OF FABRICATING PMOS DEVICES WITH EMBEDDED SIGE

(71) Applicant: SHANGHAI INTEGRATED CIRCUIT RESEARCH AND DEVELOPMENT CENTER CO. LTD., Shanghai (CN)

(72) Inventors: Shaohai ZENG, Shanghai (CN); Ming LI, Shanghai (CN); Qingyun ZUO, Shanghai (CN)

(21) Appl. No.: 15/375,139

(22) PCT Filed: Aug. 25, 2014
(86) PCT No.: PCT/CN2014/085103

§ 371 Date: Dec. 11, 2016

(30) Foreign Application Priority Data
Jun. 12, 2014 (CN) 201410260761.0

(51) Int. Cl. H01L 29/66; H01L 29/78; H01L 21/266; H01L 21/02; H01L 21/265

(52) U.S. Cl. CPC H01L 29/66636; H01L 21/02532; H01L 21/26513; H01L 21/266; H01L 29/7848

(57) ABSTRACT

A method of fabricating PMOS devices with embedded SiGe is disclosed. Prior to the selective epitaxial growth of SiGe, Ge element is implanted to the source/drain recesses and an annealing process is performed to form a strained SiGe alloy layer. Then, the strained SiGe alloy layer is used as a base layer on which another strained SiGe alloy layer is grown continually by an selective epitaxy process, so as to avoid a direct contact between the epitaxially grown strained SiGe alloy layer and the silicon substrate and reduce the defects formed at the SiGe/Si interfaces. Therefore, the stress can be applied to the PMOS channel regions without causing junction current leakage due to the defects at the SiGe/Si interfaces, which enhances the electrical performance of the PMOS devices. The fabrication method is also compatible with the conventional CMOS process.

### CROSS-REFERENCE TO RELATED APPLICATION

This application claims the priority benefit of International Patent Application Serial No.PCT/CN2014/085103, filed Aug. 25, 2014, which is related to and claims the priority benefit of China patent application serial No. 201410260761.0, filed Jun. 12, 2014. The entirety of each of the above-mentioned patent applications is hereby incorporated by reference herein and made a part of this specification.

### FIELD OF THE INVENTION

The present invention generally relates to the field of integrated circuit manufacturing, more particularly, to a method of fabricating PMOS devices with embedded SiGe.

### BACKGROUND OF THE INVENTION

With the continuous miniaturization of the VLSI, semiconductor devices are request to achieve a smaller dimension and a higher operation speed. Therefore, how to increase the drive current of the semiconductor devices has become a key to improve the device performance.

Conventionally, PMOS transistors and NMOS transistors are fabricated separately during the CMOS manufacturing process. For example, compressive stress material is introduced in the PMOS device fabrication and tensile stress material is introduced in the NMOS device fabrication, so as to apply stress to channel regions and enhance carrier mobility. For the PMOS transistors, embedded SiGe (eSiGe) technique, which forms a silicon germanium stress layer in the source/drain regions, is one of the main stress engineering approaches to enhance the hole mobility in the PMOS channel.

However, the embedded SiGe technique may produce defects at SiGe/Si interfaces, especially if germanium has a higher atom percent in the SiGe stress layer. For example, when the embedded SiGe is formed by an epitaxial growth process, the SiGe stress layer is directly formed on the Si material of the substrate. Since the lattice constant of Si-Ge bond is larger than that of Si-Si bond, stress concentration may occur at the SiGe/Si interfaces, causing high thread dislocation density of the SiGe layer. On the other hand, the profile of the source/drain recesses also affects the embedded SiGe technique greatly due to different growth schemes of the SiGe layer at different crystal orientations. Specifically, the sidewall of the S/D recess is formed at (110) crystal orientation, while the bottom of the S/D recess is formed at (001) crystal orientation. The crystal nucleation rate at the (110) crystal orientation is much greater than that at the (001) crystal orientation. As a result, the SiGe material has a rough surface at the (110) crystal orientation, causing defects in the whole SiGe stress layer.

The above defects may reduce the stress applied to the channel regions and may have an adverse effect on the performance of the PMOS transistors. Moreover, these defects may also increase PN junction current leakage between the source/drain regions and the N well or the substrate, which further worsens the performance of the PMOS transistors.

Nowadays, the above defects are mainly controlled by regulating Ge content in the SiGe and optimizing the epitaxial growth process. However, the reduction of the Ge content also decreases the stress applied to the channel, which undercuts the effect of hole mobility improvement. On the other hand, the optimized epitaxial growth process is not so effective to reduce the defects.

Accordingly, in the conventional SiGe epitaxial growth process, it is inevitable to reduce the stress applied to the channel regions by the SiGe stress layer when controlling the defects at the SiGe/Si interfaces. Therefore, there exists a need to provide a fabrication method of PMOS devices with embedded SiGe source/drain regions to solve the above problems.

### BRIEF SUMMARY OF THE DISCLOSURE

Accordingly, an objective of the present invention is to provide a method of fabricating PMOS devices with embedded SiGe, which controls the defects generated at the SiGe/Si interfaces when forming the SiGe stress layer without affecting the stress applied to the channel regions of the PMOS devices.

The method of fabricating PMOS devices with embedded SiGe comprises the following steps:
providing a semiconductor substrate on which gate structures and gate spacers are formed, and forming PMOS source/drain recesses;
covering regions outside the PMOS source/drain recesses with a photoresist layer;
implanting Ge element to the PMOS source/drain recesses;
removing the photoresist layer and performing an annealing process to form a strained SiGe alloy layer;
continuing a growth of the strained SiGe alloy layer in the PMOS source/drain recesses.

Preferably, the PMOS source/drain recesses are formed by a dry etching process.

Preferably, the Ge element is implanted by an ion implantation process.

Preferably, an implantation dosage of Ge is between 1E12/cm²-1E13/cm²; an implantation energy of Ge is between 30 KeV-80 KeV.

Preferably, an annealing temperature of the annealing process is 700° C.-900° C., an annealing time of the annealing process is 20-35 seconds.

More preferably, the annealing temperature is 800° C., the annealing time is 25 seconds.

Preferably, a selective epitaxy process is performed to continue the growth of the strained SiGe alloy layer.

Preferably, the selective epitaxy process is performed at a temperature between 600° C.-750° C. using a mixed gas of SiH2Cl2, GeH4 and H2.

Preferably, the strained SiGe alloy layer is continued to grow to fill the PMOS source/drain recesses.

Preferably, the strained SiGe alloy layer is continued to grow to at least fill the PMOS source/drain recesses.

According to the present invention, prior to the selective epitaxial growth SiGe, Ge element is implanted to the source/drain recesses followed by an annealing process. By the annealing process, the Ge element reacts with the Si element in the substrate to form a strained SiGe alloy layer, and defects generated during the formation of the strained SiGe alloy layer are repaired. Then, the strained SiGe alloy layer is used as a base layer on which another strained SiGe alloy layer is grown continually by an selective epitaxy process, so as to avoid a direct contact between the epitaxially grown strained SiGe alloy layer and the silicon substrateand reduce the defects formed at the SiGe/Si interfaces. Therefore, the stress can be applied to the channel regions of the PMOS devices without causing junction current leakage due to the defects at the SiGe/Si interfaces, which enhances the electrical performance of the PMOS devices. Furthermore, the fabrication method of the present invention is compatible with the conventional CMOS process, which provides better flexibility for process integration.

### BRIEF DESCRIPTION OF THE DRAWINGS

FIG. 1 is a flow chart illustrating the method of fabricating PMOS devices with embedded SiGe according to an embodiment of the present invention;

FIG. 2-FIG. 7 are cross-sectional views of a PMOS device during the method of fabricating PMOS devices with embedded SiGe illustrated in FIG. 1 according to the embodiment of the present invention.

### DETAILED DESCRIPTION OF THE EMBODIMENTS

The present invention will now be descried more fully hereinafter with reference to the accompanying drawings. This invention may, however, be embodied in different forms and should not be construed as limited to the embodiments set forth herein. It will be understood by those skilled in the art that various changes in form and details may be made herein without departing from the spirit and scope of the invention.

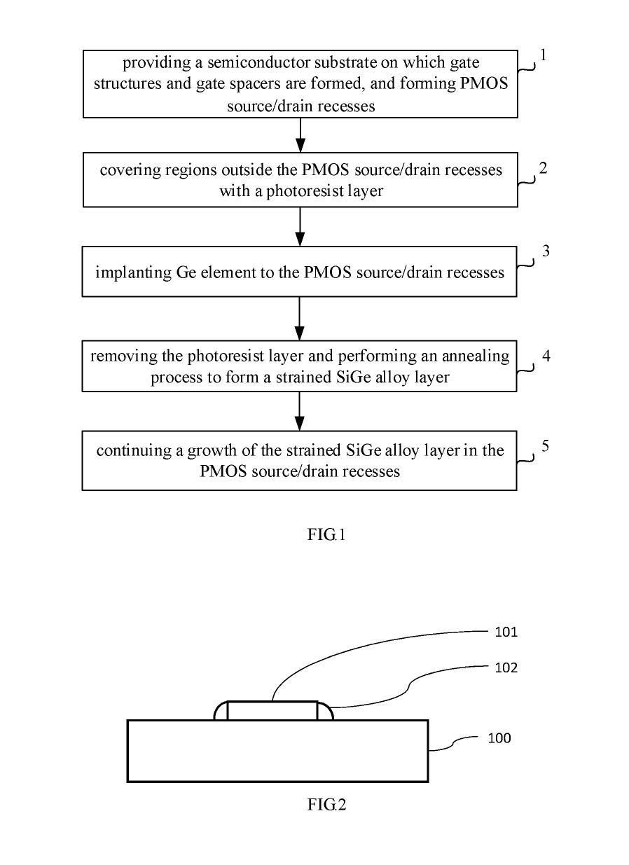

It is noted that, in the following embodiment, the fabrication of a PMOS device with embedded SiGe is described in detail according to FIG. 2-FIG. 7. The figures referred to above are not necessarily drawn to scale, should be understood to provide a representation of particular embodiments of the invention, and should not be construed as limited to the embodiments set forth herein.

FIG. 1 is a flow chart illustrating the method of fabricating PMOS devices with embedded SiGe; FIG. 2-FIG. 7 are cross-sectional views of a PMOS devioce after each step of the method illustrated in FIG. 1.

Referring to FIG. 1, the method of fabricating PMOS devices with embedded SiGe comprises the following steps:

Referring to frame 1 of FIG. 1, the first step is providing a semiconductor substrate on which gate structures and gate spacers are formed and forming PMOS source/drain recesses.

As shown in FIG. 2, a semiconductor substrate 100 is provided. A gate structure 101 and gate spacers 102 are formed on the semiconductor substrate 100. The gate structure 101 and the gate spacers 102 can be formed by the conventional manufacturing processes. The semiconductor substrate 100 can be a silicon substrate having monocrystalline silicon, polycrystalline silicon or amorphous silicon, or a SOI substrate, or a substrate with other semiconductor materials or other structures.

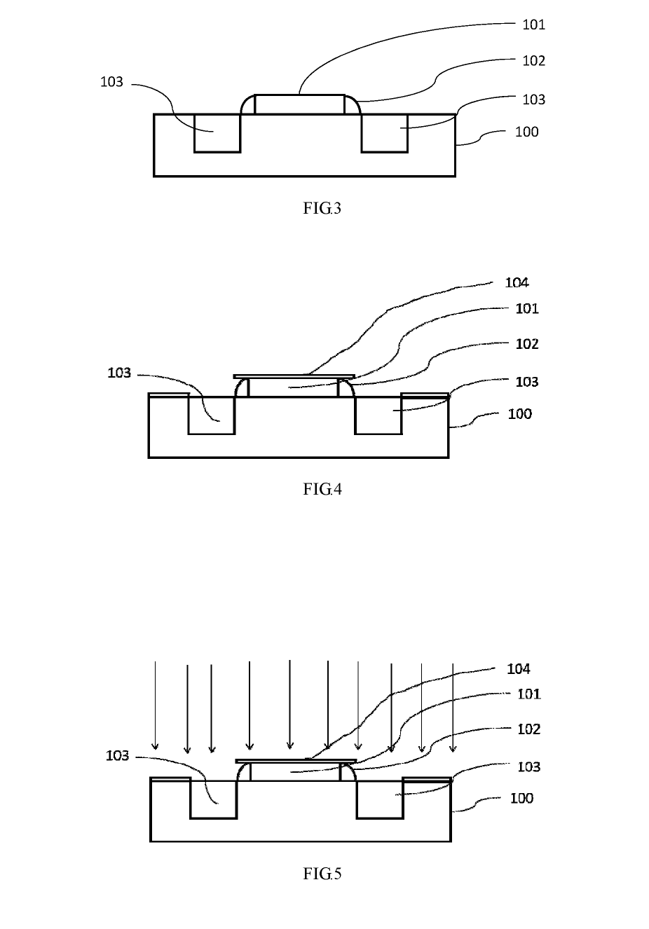

As shown in FIG. 3, PMOS source/drain recesses 103 are formed in the semiconductor substrate 100 by etching. Alternatively, the PMOS source/drain recesses 103 are formed by a dry etching process.

Referring to frame 2 of FIG. 1, the second step is covering regions outside the PMOS source/drain recesses 103 with a photoresist layer.

As shown in FIG. 4, regions outside the PMOS source/drain recesses 103 are covered by a photoresist layer 104, such that during the subsequent Ge implantation step, Ge element will not be implanted to these regions.

Referring to frame 3 of FIG. 1, the third step is implanting Ge element to the PMOS source/drain recesses.

As shown in FIG. 5, Ge element is implanted into the PMOS source/drain recesses. Actually, the implantation area covers the whole surface of the substrate (as illustrated by the down arrows). Due to the existence of the photoresist layer 104, only the PMOS source/drain recesses 103 are implanted. Alternatively, the Ge element is implanted by an ion implantation process, an implantation dosage of Ge is between 1E12/cm²-1E13/cm², an implantation energy of Ge is between 30 KeV-80 KeV. For example, the Ge element is implanted with a dosage of 1E12/cm² and an energy of 50 KeV.

During the above Ge implantation, the Ge content can be controlled at a low level by the smaller dosage between 1E12/cm²-1E13/cm², such that serious crystal damages, as well as dislocations or other defects released during strain relaxation can be avoided. Furthermore, since the implantation depth of the Ge element is controlled by the smaller implantation energy between 30 KeV-80 KeV, the strained SiGe alloy layer formed after annealing can be thinner, which minimizes the adverse effect of the reduced stress applied to the channel region by the strained SiGe alloy layer due to the low Ge content.

Referring to frame 4 of FIG. 1, the next step is removing the photoresist layer and performing an annealing process to form a strained SiGe alloy layer.

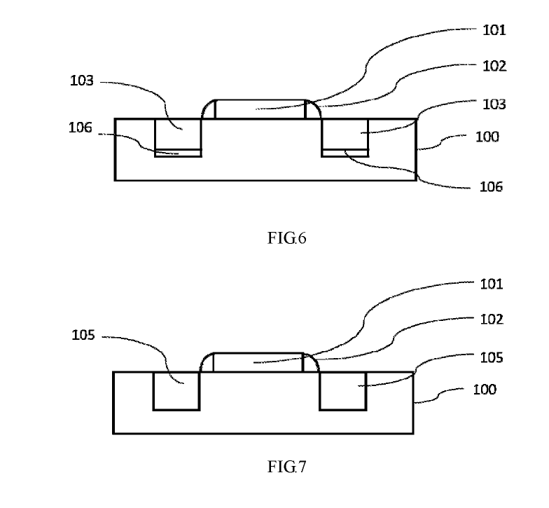

As shown in FIG. 6, the photoresist layer 104 is removed. Then the whole substrate is annealed to cause a reaction between the implanted Ge element and the Si element of the substrate to form a strained SiGe alloy layer 106. The annealing temperature is between 700° C.-900° C., the annealing time is between 20-35 seconds. The annealing process can be performed in a conventional semiconductor annealing equipment, such as a rapid thermal annealing equipment. In an embodiment, the whole substrate is annealed at a temperature of 800° C. for 25 seconds, so as to form a strained SiGe alloy layer 106 from the implanted Ge element and the Si element of the substrate.

By using the rapid thermal annealing process, a solid phase epitaxy growth (SPEG) may be carried out to form the strained SiGe alloy layer. Meanwhile, the crystal damages and defects generated during the Ge implantation can be effectively repaired.

As shown in FIG. 7, the initial strained SiGe alloy layer 105 is continued to grow by performing a selective epitaxy process to fill the source/drain recesses 103, so as to apply required stress to the channel region. The selective epitaxy process can be performed at a temperature between 600° C.-750° C. using a mixed gas of SiH₂Cl2, GeH₄ and H₂, which is not limited thereto. For example, the selective epitaxy process is performed at a temperature of 700° C. using a mixed gas of SiH₂Cl2, GeH₄ and H2.

In another embodiment, the strained SiGe alloy layer 105 is continued to grow by performing a selective epitaxy process to at least fill the source/drain recesses 103, and can exceed the source/drain recesses 103, so as to apply appropriate stress to the channel region or meet other requirements.

After the formation of the PMOS device with embedded SiGe, other CMOS process steps can be performed. For example, metal silicide (e.g. NiPt) can be formed on the source/drain regions and the gate structure, then an interlayer dielectric can be deposited, contact holes can be etched and a Cu BEOL process can be performed. The processing steps can be performed by conventional methods known by those skilled in the art, which are omitted herein.

It is noted that, since the Si-Ge bond has a larger lattice constant than that of the Si-Si bond, stress concentration may form at the SiGe/Si interfaces when the strained SiGe layer is directly epitaxially grown on the Si substrate, which generates defects at the interfaces. As a result, the SiGe layer is formed with high thread dislocation density, and the defects are difficult to be reduced. The main conventional measurements to reduce these defects include Ge content regulation and epitaxy process optimization. However, the stress applied to the channel also decreases with the reduction of the Ge content, which undercuts the effect of hole mobility improvement; and the optimized epitaxy process is not so effective to reduce the defects. Furthermore, the SiGe layer has a rough surface, also causing defects in the whole SiGe stress layer. The above defects reduce the stress applied to the channel and affect the performance of the PMOS devices. Moreover, the above defects also increase PN junction current leakage between the source/drain regions and the N well or the substrate, which further worsens the performance of the PMOS devices.

Compared with the conventional technology, prior to the selective epitaxial growth of the strained SiGe alloy layer, Ge element is implanted to the source/drain recesses followed by an annealing process. During the annealing process, the Ge element reacts with the Si element in the substrate to form a strained SiGe alloy layer, defects generated during the formation of the strained SiGe alloy layer are repaired. The strained SiGe alloy layer has a smooth surface. Then, the strained SiGe alloy layer is used as a base layer on which another strained SiGe alloy layer is grown continually by an selective epitaxy process, so as to avoid a direct contact between the epitaxially grown strained SiGe alloy layer and the silicon substrate. The Si-Ge bond of the new strained SiGe alloy layer, which is directly formed by the selective epitaxy process utilizing processing gas, has a lattice constant matched with that of the Si-Ge bond of the underlying strained SiGe alloy base layer which is formed by annealing, which reduces the mismatch dislocation and suppresses defects generated at SiGe/Si interfaces. Furthermore, since the new strained SiGe alloy layer is nucleated and grown uniformly on the smooth surface of the underlying strained SiGe alloy base layer formed by annealing, the whole strained SiGe alloy layer has a better smoothness, so as to obtain a superior quality. Accordingly, the stress can be applied to the channel region without causing junction current leakage due to defects generated at SiGe/Si interfaces, thereby improving the electrical performance of the PMOS devices. In addition, the fabrication method is also compatible with the conventional CMOS process, which provides better flexibility for process integration.

While this invention has been particularly shown and described with references to preferred embodiments thereof, it will be understood by those skilled in the art that various changes in form and details may be made herein without departing from the spirit and scope of the invention as defined by the appended claims.

1. A method of fabricating PMOS devices with embedded SiGe comprises:
providing a semiconductor substrate on which gate structures and gate spacers are formed, and forming PMOS source/drain recesses;
covering regions outside the PMOS source/drain recesses with a photoresist layer;
implanting Ge element to the PMOS source/drain recesses;
removing the photoresist layer and performing an annealing process to form a strained SiGe alloy layer;
continuing a growth of the strained SiGe alloy layer in the PMOS source/drain recesses.

2. The method according to claim 1, wherein the PMOS source/drain recesses are formed by a dry etching process.

3. The method according to claim 1, wherein the Ge element is implanted by an ion implantation process.

4. The method according to claim 3, wherein an implantation dosage of Ge is between 1E12/cm2-1E13/cm2; an implantation energy of Ge is between 30 KeV-80 KeV.

5. The method according to claim 1, wherein an annealing temperature of the annealing process is 700° C.-900° C., an annealing time of the annealing process is 20-35 seconds.

6. The method according to claim 5, wherein the annealing temperature is 800° C., the annealing time is 25 seconds.

7. The method according to claim 1, wherein a selective epitaxy process is performed to continue the growth of the strained SiGe alloy layer.

8. The method according to claim 7, wherein the selective epitaxy process is performed at a temperature between 600° C.-750° C. using a mixed gas of SiH2Cl2, GeH4 and H2.

9. The method according to claim 1, wherein the strained SiGe alloy layer is continued to grow to fill the PMOS source/drain recesses.

10. The method according to claim 1, wherein the strained SiGe alloy layer is continued to grow to at least fill the PMOS source/drain recesses.
